(19) United States
(12) Patent Application Publication
(10) Pub. No.: US 2007/0212861 A1
(43) Pub. Date: Sep. 13, 2007

(54) LASER SURFACE ANNEALING OF ANTIMONY DOPED AMORPHIZED SEMICONDUCTOR REGION

(75) Inventors: Dureseti Chidambarrao, Weston, CT (US); Sameer H. Jain, Beacon, NY (US); William K. Henson, Peekskill, NY (US); Kern Rim, Yorktown Heights, NY (US)

Correspondence Address: SCULLY SCOTT MURPHY & PRESSER, PC, 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 11/308,108

(22) Filed: Mar. 7, 2006

(51) Int. Cl. H01L 21/425

(52) U.S. Cl. 438/530

(57) ABSTRACT

A sheet resistance stabilized recrystallized antimony doped region may be formed within a semiconductor substrate by annealing a corresponding antimony doped amorphized region at a temperature from about 1050° C. to about 1400° C. for a time period from about 0.1 to about 10 milliseconds. Preferably, a laser surface treatment is used. The laser surface treatment preferably uses a solid phase epitaxy. In addition, the antimony doped region may be co-doped with at least one of a phosphorus dopant and an arsenic dopant. The antimony dopant and the laser surface treatment lend sheet resistance stability that is otherwise absent when forming solely phosphorus and/or arsenic doped regions.

### BACKGROUND OF THE INVENTION

1. Field of the Invention

The invention relates to methods for fabricating doped regions within semiconductor structures. More particularly, the invention relates to methods for fabricating enhanced performance doped regions within semiconductor structures.

2. Description of the Related Art

Semiconductor devices typically use doped regions as either active semiconductor regions or as conductive regions within semiconductor structures. The doped regions are typically formed incident to ion implantation using either a p-conductivity type dopant (i.e., a boron containing dopant) or an n-conductivity type dopant (i.e., a phosphorus containing dopant or an arsenic containing dopant).

A particularly common use of a doped region within a semiconductor substrate is a source/drain region within a field effect device. Field effect transistor devices are particularly common. To optimize field effect device performance, source/drain regions typically have high levels of active dopants (e.g., from about 1e20 to about 1e21 dopant atoms per cubic centimeter concentration, or from about 1e14 to about 1e16 dopant ions per square centimeter dosage). The high levels of active dopants yield low sheet resistances of doped regions (e.g., from about 150 to about 250 ohms/square).

Various factors influence dopant activation within doped regions, such as source/drain regions within field effect devices. Included among the factors are dopant selection and type, as well as doped region thermal annealing characteristics and related considerations.

Various novel dopant activation methods and materials are known in the semiconductor fabrication art. In particular, Yu et al., in U.S. Pat. No. 6,893,930, teaches an ion implant method for fabricating at least one of: (1) a shallow source/drain extension region; and (2) a deeper source/drain conductor region, within a field effect transistor. The ion implant method disclosed in Yu et al. uses an antimony dopant that may be activated using either: (1) a thermal annealing process at a temperature less than about 950° C.; or (2) a solid phase epitaxy process at a temperature less than about 650° C.

Semiconductor device and structure dimensions, including source/drain region dimensions and other doped region dimensions, are certain to continue to decrease. As a result thereof, a need for methods and materials that provide enhanced performance doped regions within semiconductor substrates is certain to continue to increase.

### SUMMARY OF THE INVENTION

The present invention provides several methods for forming a doped region within a semiconductor substrate.

The inventive methods are predicated upon a thermal stabilizing affect of an antimony dopant used alone, or as a co-dopant, within a doping and amorphizing method for forming a doped region within a semiconductor substrate.

One method in accordance with the invention includes forming an antimony doped amorphized region within a semiconductor substrate. The method also includes annealing the antimony doped amorphized region at a temperature from about 1050° C. to about 1400° C. for a time period from about 0.1 to about 10 milliseconds to form an annealed antimony doped region.

Another method in accordance with the invention also includes forming an antimony doped amorphized region within a semiconductor substrate. This other method also includes laser annealing the antimony doped amorphized region to form a laser annealed antimony doped region. The laser annealing provides a solid phase epitaxy of the antimony doped amorphized region absent melting of the antimony doped amorphized region.

Yet another method in accordance with the invention includes forming an antimony co-doped amorphized region within a semiconductor substrate. The antimony co-doped amorphized region further includes at least one of a phosphorus co-dopant and an arsenic co-dopant. This other method also includes laser annealing the antimony co-doped amorphized region to form a laser annealed antimony co-doped region. The laser annealing step provides a solid phase epitaxy of the antimony co-doped amorphized region absent melting of the antimony co-doped amorphized region.

### BRIEF DESCRIPTION OF THE DRAWINGS

The objects, features and advantages of the invention are understood within the context of the Description of the Preferred Embodiments, as set forth below. The Description of the Preferred Embodiments is understood within the context of the accompanying drawings, which form a material part of this disclosure, wherein:

FIG. 1 to FIG. 6 show a series of schematic cross-sectional diagrams illustrating the results of progressive stages in fabricating a field effect transistor in accordance with one embodiment of the invention.

FIG. 7 to FIG. 12 show a series of schematic cross-sectional diagrams illustrating the results of progressive stages in fabricating a field effect transistor in accordance with another embodiment of the invention.

FIG. 13 to FIG. 18 show a series of schematic cross-sectional diagrams illustrating the results of progressive stages in fabricating a field effect transistor in accordance with yet another embodiment of the invention.

FIG. 19 shows a graph of Sheet Resistance versus Laser Surface Anneal Temperature for specific dopant compositions when thermally annealing an amorphized doped region within a semiconductor substrate in accordance with the invention, and not in accordance with the invention.

### DESCRIPTION OF THE INVENTION

The present invention, which provides a semiconductor structure including a doped region within a substrate and a method of fabricating the same, will now be described in greater detail by referring to the following discussion and drawings that accompany the present application. It is observed that the drawings of the present application are provided for illustrative proposes and, as such, the drawings are not drawn to scale.

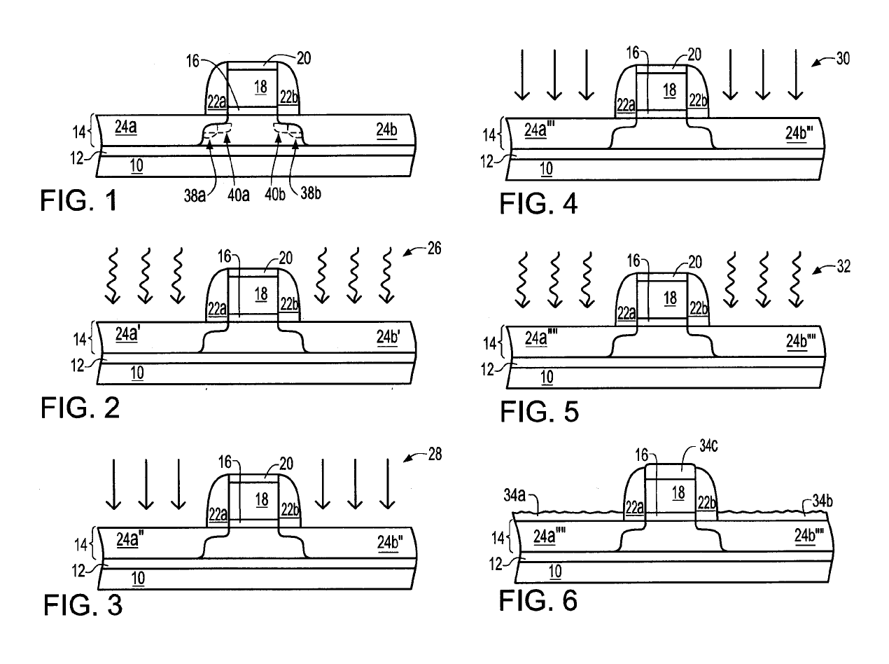

Reference is first made to FIGS. 1-6 which show a series of schematic cross-sectional diagrams illustrating the results of progressive stages in fabricating a field effect transistor device in accordance with one embodiment of the invention. This embodiment of the present invention is referred to hereinafter as the ‘first’ embodiment.

FIG. 1 shows a semiconductor substrate 10. A buried dielectric layer 12 is located upon the semiconductor substrate 10. A surface semiconductor layer 14 is located upon the buried dielectric layer 12. In an aggregate, the semiconductor substrate 10, the buried dielectric layer 12 and the surface semiconductor layer 14 comprise a semiconductor-on-insulator substrate.

The semiconductor substrate 10 may comprise any of several semiconductor materials. Non-limiting examples include silicon, germanium, silicon-germanium alloy, silicon carbide, silicon-germanium carbide alloy and compound (i.e., III-V and II-VI) semiconductor materials. Non-limiting examples of compound semiconductor materials include gallium arsenide, indium arsenide and indium phosphide semiconductor materials. Typically, the semiconductor substrate 10 has a thickness from about 1 to about 3 mils.

The buried dielectric layer 12 may comprise any of several dielectric materials. Non-limiting examples include oxides, nitrides and oxynitrides, particularly of silicon, but oxides, nitrides and oxynitrides of other elements are not excluded. The buried dielectric layer 12 may comprise a crystalline or a non-crystalline dielectric material, with crystalline dielectrics being highly preferred. The buried dielectric layer 12 may be formed using any of several methods. Non-limiting examples include ion implantation methods, thermal or plasma oxidation or nitridation methods, chemical vapor deposition methods and physical vapor deposition methods. Typically, the buried dielectric layer 12 comprises an oxide of the semiconductor material from which is comprised, i.e., an oxide of the semiconductor substrate 10. Typically, the buried dielectric layer 12 has a thickness from about 50 to about 200 angstroms.

The surface semiconductor layer 14 may comprise any of the several semiconductor materials from which the semiconductor substrate 10 may be comprised. The surface semiconductor layer 14 and the semiconductor substrate 10 may comprise either identical or different semiconductor materials with respect to chemical composition, dopant concentration and crystallographic orientation. Typically, the surface semiconductor layer 14 has a thickness from about 500 to about 1000 angstroms.

The semiconductor-on-insulator substrate that is illustrated in FIG. 1 may be fabricated using any of several methods. Non-limiting examples include lamination methods, layer transfer methods and separation by implantation of oxygen (SIMOX) methods.

Although the first embodiment illustrates the invention within the context of a semiconductor on-insulator substrate comprising the semiconductor substrate 10, the buried dielectric layer 12 and the surface semiconductor layer 14, neither the embodiment, nor the invention is so limited. Rather, the present invention may alternatively be practiced using a bulk semiconductor substrate (that would otherwise result from absence of the buried dielectric layer 12 under circumstances where the semiconductor substrate 10 and the surface semiconductor layer 14 have identical chemical composition and crystallographic orientation). The embodiment also contemplates use of a hybrid orientation (HOT) substrate that has multiple crystallographic orientations within a single semiconductor substrate.

FIG. 1 also shows (in cross-section) a field effect transistor device located within and upon the surface semiconductor layer 14 of the semiconductor-on-insulator substrate. The field effect transistor device comprises: (1) a gate dielectric 16 located upon the surface semiconductor layer 14; (2) a gate electrode 18 located upon the gate dielectric 16; (3) a capping layer 20 located upon the gate electrode 18; (4) a pair (in cross-section, but not in plan view) of optional spacer layers 22a and 22b located adjoining a pair of opposite sidewalls of the gate dielectric 16, the gate electrode 18 and the capping layer 20; and (5) a pair of source/drain regions 24a and 24b located within the surface semiconductor layer 14. The pair of source/drain regions 24a and 24b is separated by a channel region that is aligned beneath the gate electrode 18. Each of the foregoing layers and structures may comprise materials and have dimensions that are conventional in the semiconductor fabrication art. Each of the foregoing layers and structures may also be formed using methods that are conventional in the semiconductor fabrication art.

The gate dielectric 16 may comprise conventional dielectric materials such as oxides, nitrides and oxynitrides of silicon that have a dielectric constant from about 4 to about 20, measured in a vacuum. Alternatively, the gate dielectric 16 may comprise generally higher dielectric constant dielectric materials having a dielectric constant from about 20 to at least about 100. Such higher dielectric constant dielectric materials may include, but are not limited to: hafnium oxides, hafnium silicates, titanium oxides, barium-strontium-titantates (BSTs) and lead-zirconate-titanates (PZTs). The gate dielectric 16 may be formed using any of several methods that are appropriate to its material(s) of composition. Included, but not limiting are thermal or plasma oxidation or nitridation methods, chemical vapor deposition methods and physical vapor deposition methods. Typically, the gate dielectric 16 comprises a thermal silicon oxide dielectric material that has a thickness from about 10 to about 70 angstroms.

The gate electrode 18 may comprise materials including, but not limited to: certain metals, metal alloys, metal nitrides and metal silicides, as well as laminates thereof and composites thereof. The gate electrode 18 may also comprise doped polysilicon and SiGe materials (i.e., having a dopant concentration from about 1e18 to about 1e22 dopant atoms per cubic centimeter) and polycide materials (doped polysilicon/metal silicide stack materials). Similarly, the foregoing materials may also be formed using any of several methods. Non-limiting examples include salicide methods, chemical vapor deposition methods and physical vapor deposition methods, such as, but not limited to: evaporative methods and sputtering methods. Typically, the gate electrode 18 comprises a doped polysilicon material that has a thickness from about 600 to about 2000 angstroms.

The capping layer 20 may comprise any of several capping materials. Dielectric capping materials are most common. The dielectric capping materials may include, but are not limited to: oxides, nitrides and oxynitrides of silicon, but oxides, nitrides and oxynitrides of other elements are not excluded. The dielectric capping materials may be formed using any of the several methods that may be used for forming the buried dielectric layer 12. Typically, the capping layer 20 comprises a silicon nitride dielectric material that has a thickness from about 100 to about 300 angstroms.

The pair of optional spacer layers 22a and 22b may comprise materials including, but not limited to: conductor materials and dielectric materials. Conductor spacer materials are less common, but are nonetheless known. Dielectric spacer materials are more common. The spacer materials may be formed using methods analogous, equivalent or identical to the methods that are used for forming the capping layer 20. The spacer layers 22a and 22b are also formed with the distinctive inward pointing spacer shape by using a blanket layer deposition and anisotropic etchback method that requires that the pair of spacer layers 22a and 22b comprises a different spacer material from the capping layer 20. Typically, the pair of spacer layers 22a and 22b comprises a silicon oxide dielectric material when the capping layer 20 comprises a silicon nitride dielectric material.

Finally, the pair of source/drain regions 24a and 24b comprises a generally conventional n-conductivity type dopant that will typically be either a phosphorus dopant or an arsenic dopant. As is understood by a person skilled in the art, and as will be illustrated in greater detail within the context of the third embodiment that follows, the pair of source/drain regions 24a and 24b is formed using a two step ion implantation method. A first ion implantation process step within the method uses the gate electrode 18, absent the pair of spacer layers 22a and 22b, as a mask to form a pair of extension regions each of which extends beneath the pair of spacer layers 22a and 22b. A second ion implantation process step uses the gate electrode 18 and the pair of spacer layers 22a and 22b as a mask to form the larger contact region portions of the pair of source/drain regions 22a and 22b, while simultaneously incorporating the pair of extension regions. n-conductivity type dopant levels are from about 1e19 to about 1e21 dopant atoms per cubic centimeter within each of the pair of source/drain regions 24a and 24b. Extension regions within the pair of source/drain regions 24a and 24b may under certain circumstances be more lightly doped than contact regions with the pair of source/drain regions, although such differential doping concentrations are not a requirement of the invention.

As will become clear within the context of further disclosure below, neither the instant embodiment in particular, nor the invention in general, is limited to further processing of a source/drain region 24a or 24b within the field effect transistor structure that is illustrated in FIG. 1. Rather the embodiment and the invention may be practiced within the context of a doped region within a field effect transistor structure other than illustrated in FIG. 1, wherein such a field effect transistor structure may comprise additional doped regions. Such additional doped regions may include, but are not limited to: buffer regions and halo regions.

For reference purposes, locations of buffer regions and halo regions are illustrated in phantom in FIG. 1. For clarity, the buffer region and halo region structures are omitted from remaining figures within the instant disclosure. A pair of buffer regions 38a and 38b is located and sized as a pair of additional steps interposed between the extension region portions and the contact region portions within the pair of source/drain regions 24a and 24b. The pair of buffer regions 38a and 38b also comprises an n-conductivity dopant. A pair of halo regions 40a and 40b appear as a halo beneath each of the pair of extension regions within each of the pair of source/drain regions 24a and 24b. The pair of halo regions 40a and 40b comprises a p-conductivity type dopant.

Finally, the present invention may, in a general terms, also be practiced within the context of doped regions that are not used within a field effect device or a field effect transistor device. In that regard, doped regions that are used within semiconductor devices including, but not limited to: semiconductor based diodes and semiconductor based resistors, may also benefit from the invention. Thus, a doped region in accordance with the invention may be used within both active devices and passive devices.

FIG. 2 shows an activation annealing treatment 26 (i.e., such as, but not limited to: a rapid thermal annealing, a spike anneal, or a furnace annealing) of the semiconductor structure whose schematic cross-sectional diagram is illustrated in FIG. 1. The activation annealing treatment 26 may be provided as a rapid thermal annealing at a temperature from about 500° C. to about 1100° C. for a time period from about 1 sec to about 10 minutes. Rapid thermal annealing is generally performed at a shorter duration than furnace annealing. The purpose of the activation annealing treatment 26 is to provide a preliminary activation of doped regions within the field effect transistor that is illustrated in FIG. 1. To that end, the activation annealing treatment 26 serves to thermally anneal, and at least partially recrystallize, any ion implant damage to the surface semiconductor layer 14 that is illustrated in FIG. 1. The activation annealing treatment 26 that is illustrated in FIG. 2 provides a pair of activated annealed source/drain regions 24a′ and 24b′ from the pair of source/drain regions 24a and 24b that is illustrated in FIG. 1.

FIG. 3 shows a dose of amorphizing ions 28 implanted into the pair of activated annealed source/drain regions 24a′ and 24b′ that is illustrated in FIG. 2. Thus, a pair of amorphized source/drain regions 24a″ and 24b″ is formed from the pair of activated annealed source/drain regions 24a′ and 24b′. The dose of amorphizing ions 28 may comprise amorphizing ions such as, but not limited to: argon, xenon, krypton, germanium and silicon amorphizing ions. Germanium amorphizing ions are common and desirable. When using germanium amorphizing ions, the dose of amorphizing ions 28 is implanted at an aerial dose from about 3e14 to about 5e14 ions per square centimeter, while using an ion implantation energy from about 15 to about 35 keV. Intended is an amorphising atom concentration within the pair of amorphized source/drain regions 24a″ and 24b″ from about 1e20 to about 1e21 per cubic centimeter. Lower ion implantation energies are generally used in conjunction with a semiconductor-on-insulator substrate. Higher ion implantation energies are generally used in conjunction with a bulk semiconductor substrate. Within the context of a semiconductor-on-insulator substrate, the dose of amorphizing ions 28 is not intended to completely amorphize the pair of activated annealed source/drain regions 24a′ and 24b′ (i.e., not extend beyond the projected range of implanted dopants used for forming the pair of source/drain regions 24a and 24b) when forming the pair of amorphized source/drain regions 24a″ and 24b″, since it is desirable to have some crystalline seed material present for recrystallization of the pair of amorphized source/drain regions 24a″ and 24b″.

FIG. 4 shows a dose of antimony dopant ions 30 that is implanted into the pair of amorphized source/drain regions 24a″ and 24b″ to provide a pair of antimony doped amorphized source/drain regions 24a′″ and 24b′″. The dose of antimony dopant ions 30 is generally provided at a higher concentration, but also possibly a lower implanted range, than the dose of amorphizing ions 28. The dose of antimony dopant ions 30 is provided at a dose from about 1e15 to about 1e16 antimony dopant atoms per square centimeter, to yield the pair of antimony doped amorphized source/drain regions 24a′″ and 24b′″. Preferably, the antimony implant energy is chosen such that the peak of the implanted antimony profile is close to an eventual silicide/silicon interface of a pair of silicide layers located upon the pair of antimony doped amorphized source/drain regions 24a′″ and 24b′″.

FIG. 5 shows a laser surface annealing treatment 32 that is used to treat the pair of antimony doped amorphized source/drain regions 24a′″ and 24b′″ to provide a pair of recrystallized antimony doped source/drain regions 24a″″ and 24b″″. The laser surface annealing treatment 32 is provided to yield a surface temperature of the pair of antimony doped amorphized source/drain regions 24a′″ and 24b′″ from about 1050° C. to about 1400° C. (and more preferably from about 1200° C. to about 1350° C.) for a time period from about 0.1 to about 10 milliseconds, when forming therefrom the pair of recrystallized antimony doped source/drain regions 24a″″ and 24b″″. The invention may also employ annealing treatments other than laser surface annealing treatments provided that the foregoing temperature and time limitations are met (i.e., from about 1050° C. to about 1400° C. (and more preferably from about 1200° C. to about 1350° C.) for a time period from about 0.1 to about 10 milliseconds). Such other annealing treatments may include, but are not limited to: flash annealing treatments.

As will be illustrated within the context of experimental data that follows, the use of a laser surface annealing method when thermally annealing an antimony doped amorphized region will provide for a lower sheet resistance and an enhanced sheet resistance stability to subsequent thermal annealing, in comparison with an alternative rapid thermal annealing (i.e., 1000° C. to 1200° C. for about 1 to about 100 seconds) of the same antimony doped amorphized region. A lower sheet resistance is intended as a sheet resistance that may be lower than 200 ohms per square. An enhanced sheet resistance stability to subsequent thermal annealing is intended to include thermal annealing in a range from about 400° C. to about 700° C., that is often used for manufacturing processes such as but not limited to silicidation processes. The lower sheet resistance and enhanced sheet resistance stability are desirable within the pair of recrystallized antimony doped source/drain regions 24a″″ and 24b″″.

FIG. 6 first shows the results of stripping the optional capping layer 20 from the semiconductor structure whose schematic cross-sectional diagram is illustrated in FIG. 5. The capping layer 20 may be stripped using methods and materials that are otherwise generally conventional in the semiconductor fabrication art. Wet chemical etch methods and dry plasma etch methods, or combinations thereof, may be used.

FIG. 6 also shows a series of silicide layers 34a, 34b and 34c located one each upon the pair of recrystallized antimony doped source/drain regions 24a″″ and 24b″″, and the gate electrode 18. Note that the silicide 34c located atop the gate electrode 18 is optional and need not be formed. For example, and when the gate electrode 18 is a metal gate or a silicide gate, a separate silicide is not formed unless a source of silicon is present. When the gate electrode 18 is composed of a Si-containing material such as polySi or SiGe, the silicide 34c is formed thereon.

The series of silicide layers 34a, 34b and 34c may comprise any of several silicide materials. Non-limiting examples of silicide materials include titanium, tungsten, vanadium, cobalt, nickel and platinum silicide materials. The series of silicide layers 34a, 34b and 34c may be formed using methods including, but not limited to: salicide (i.e., self-aligned silicidation) methods, chemical vapor deposition methods and physical vapor deposition methods. Salicide methods are most common. Typically, each of the silicide layers 34a, 34b and 34c has a thickness from about 50 to about 200 angstroms, although each of the silicide layers 34a, 34b and 34c need not have the same silicide composition. Typically, each of the silicide layers 34a, 34b and 34c is formed using a salicide method.

As stated above FIGS. 1-6 show a series of schematic cross-sectional diagrams illustrating the results of progressive stages in fabricating a field effect transistor in accordance with a first embodiment of the invention. The first embodiment comprises a method that, in turn, includes a series of process steps that provides for: (1) forming a pair of antimony doped amorphized source/drain regions 24a′″ and 24b′″ within a semiconductor substrate; and (2) recrystallizing the pair of antimony doped amorphized source/drain regions 24a′″ and 24b′″ to form a pair of recrystallized antimony doped source/drain regions 24a″″ and 24b″″ within the semiconductor substrate. Within the first embodiment and the invention, the recrystallizing is effected while using a laser surface annealing method.

In accordance with the instant embodiment and the invention, a beneficial effect (i.e., low and thermally stable sheet resistance) may be obtained when the laser surface annealing of the antimony doped amorphized source/drain regions 24a′″ and 24b′″ provides for a solid phase epitaxial growth and recrystallization of the antimony doped amorphized source/drain regions 24a′″ and 24b′″ when forming the recrystallized antimony doped source/drain regions 24a″″ and 24b″″.

In accord with further disclosure below, the foregoing process steps and materials sequences in accordance with the first embodiment provide for a lower and more stable sheet resistance for the pair of recrystallized antimony doped source/drain regions 24a″″ and 24b″″, when fabricating the semiconductor structure that is illustrated in FIG. 6.

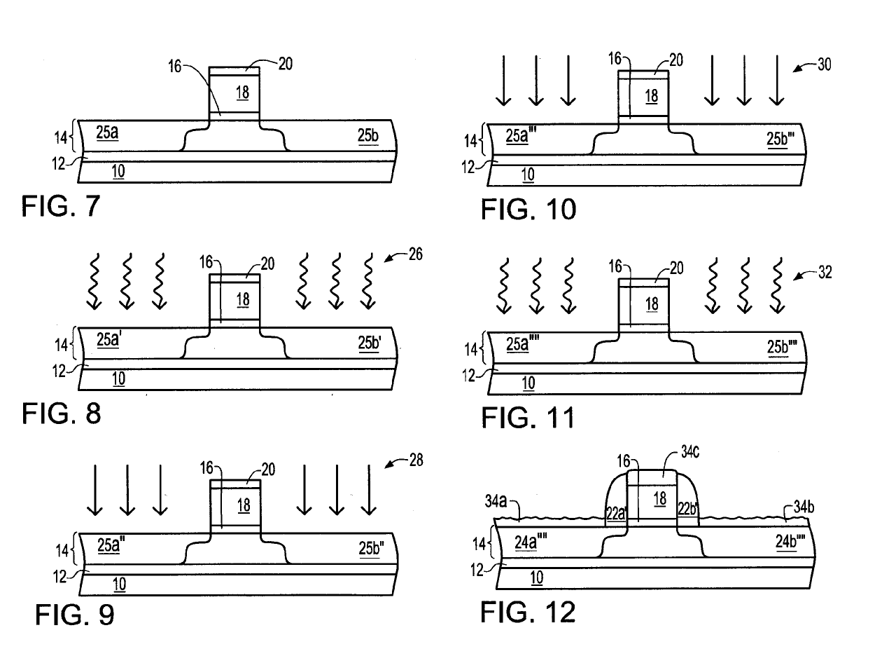

FIGS. 7-12 show a series of schematic cross-sectional diagrams illustrating the results of progressive stages in fabricating a field effect transistor in accordance with another embodiment of the invention. This other embodiment is referred to herein as the second embodiment of the present invention.

FIG. 7 to FIG. 12 correspond generally with FIG. 1 to FIG. 6 with respect to the specific sequence comprising: (1) activation annealing; (2) amorphization; (3) antimony doping; and (4) laser surface annealing process steps illustrated by reference numerals 26, 28, 30 and 32 that are illustrated in FIG. 2 to FIG. 5. However, the second embodiment that is illustrated within FIG. 7 to FIG. 12 differs from the first embodiment with respect to a structural aspect of a field effect transistor that is treated with the foregoing series of process steps.

Within the second embodiment that is illustrated in FIG. 7 to FIG. 12, and in comparison with the first embodiment that is illustrated in FIG. 1 to FIG. 6, identical reference numerals are intended as referencing analogous, equivalent or identical structures

FIG. 7 corresponds otherwise identically with FIG. 1, but with the absence of the pair of spacer layers 22a and 22b located adjoining the gate dielectric layer 16, the gate electrode 18 and the capping layer 20. The semiconductor structure that is illustrated in FIG. 7 may be formed from the semiconductor structure that is illustrated in FIG. 1 by simply stripping the pair of spacer layers 22a and 22b from the semiconductor structure that is illustrated in FIG. 1. Alternatively, a reversed sequencing of the two step ion implantation process steps that are used for forming the pair of source/drain regions 24a and 24b (incorporating the pair of extension regions that align to the pair of gate electrode 18 sidewalls) may be used. This latter approach uses the pair of spacers 22a and 22b as a mask for forming the pair of source/drain regions 24a and 24b absent the pair of extension regions first. The pair of spacer layers 22a and 22b is stripped and the pair of extension regions is then formed. The pair of spacer layers 22a and 22b thus serve as a pair of “disposable” spacer layers. An identical field effect transistor structure, as illustrated in FIG. 7, results from either of the two foregoing process sequences.

The pair of source/drain regions 25a and 25c that is illustrated in FIG. 7 is otherwise analogous, equivalent or identical to the pair of source/drain regions 24a and 24b that is illustrated in FIG. 1, but they are renumbered with new reference numerals to provide clarity incident to further processing of the semiconductor structure whose schematic cross-sectional diagram is illustrated in FIG. 7. FIG. 8, FIG. 9, FIG. 10 and FIG. 11 show a series of semiconductor structures that also correspond with the semiconductor structures of FIG. 2, FIG. 3, FIG. 4 and FIG. 5, but also absent the pair of spacer layers 22a and 22b. The sequence of process steps that uses: (1) the activation annealing treatment 26 (FIG. 8); (2) the dose of amorphizing ion 28 (FIG. 9); (3) the dose of antimony dopant ions 30 (FIG. 10); and (4) the laser surface annealing treatment 32 (FIG. 11) provide a corresponding progression of: (1) a pair of activated annealed source/drain regions 25a′and 25b′ from the pair of source/drain regions 25a and 25b (FIG. 7 and FIG. 8); (2) a pair of amorphized source/drain regions 25a″ and 25b″ from the pair of activated annealed source/drain regions 25a′ and 25b′ (FIG. 8 and FIG. 9); (3) a pair of antimony doped amorphized source/drain regions 25a′″ and 25b′″ from the pair of amorphized source/drain regions 25a″ and 25b″ (FIG. 9 and FIG. 10); and (4) a pair of recrystallized antimony doped source/drain regions 25a″″ and 25b″″ from the pair of antimony doped amorphized source/drain regions 25a′″ and 25b′″ (FIG. 10 and FIG. 11).

The foregoing pairs of source/drain regions within the second embodiment correspond with corresponding pairs of source/drain regions within FIG. 2 to FIG. 5, but with the exception that the pair of extension regions beneath the pair of spacer layers 22a and 22b (that are present in FIG. 1 to FIG. 5 but absent within FIG. 7 to FIG. 11) are fully exposed to: (1) the activation annealing treatment 26 illustrated in FIG. 8; (2) the dose of amorphizing ions 28 illustrated in FIG. 9; (3) the dose of antimony dopant ions 30 illustrated in FIG. 10; and (4) the laser surface annealing treatment 32 illustrated in FIG. 11. Thus, within the second embodiment, but not the first embodiment, the extension region portions of the pair of recrystallized antimony doped source/drain regions 25a″″ and 25b″″ also have a low and stable sheet resistance incident to presence of antimony dopant atoms and use of a laser surface annealing method.

FIG. 12 corresponds with FIG. 6, but with the presence of the pair of recrystallized antimony doped source/drain regions 25a″″ and 25b″″, and the presence of the pair of spacer layers 22a′ and 22b′. Spacer layers 22a′ and 22b′ are dimensioned similarly to spacer layers 22a and 22b that are illustrated in FIG. 6, but formed separately.

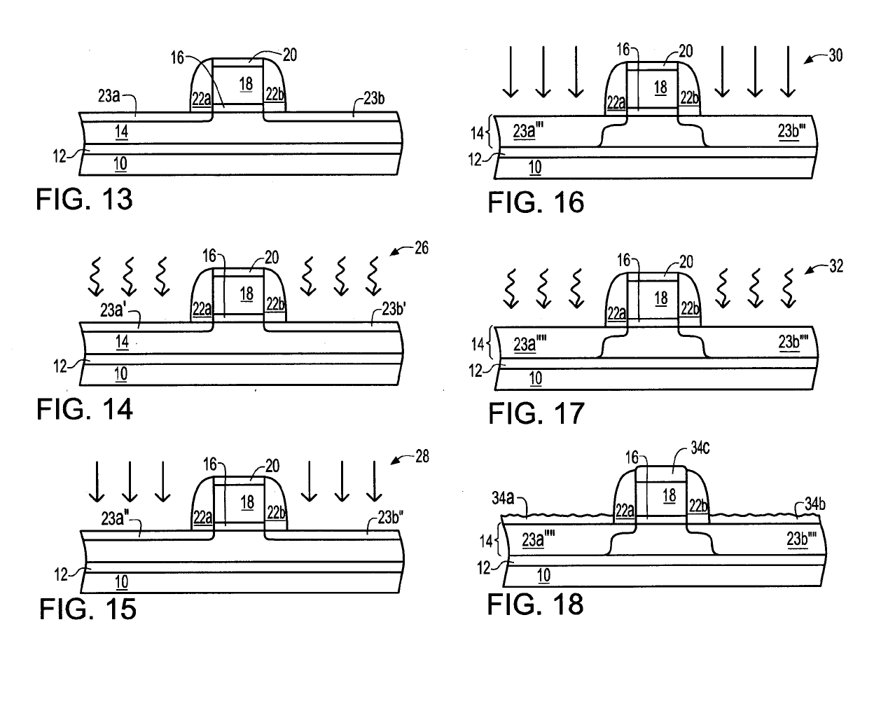

FIGS. 13-18 show a series of schematic cross-sectional diagrams illustrating the results of progressive stages in fabricating a field effect transistor in accordance with a yet other embodiment of the invention. This yet other embodiment of the present invention is referred to herein as the third embodiment of the present invention.

FIG. 13 to FIG. 18 also correspond generally with FIG. 1 to FIG. 6 with respect to the specific sequence of activation annealing, amorphizing, antimony doping and laser surface annealing process steps in accordance with the first embodiment. However, the third embodiment whose schematic cross-sectional diagrams are illustrated in FIG. 13 to FIG. 18 differs from the first embodiment with respect to stage of fabrication of a field effect transistor device at which the foregoing series of process steps is implemented.

Within the third embodiment that is illustrated in FIG. 13 to FIG. 18, and in comparison with the first embodiment that is illustrated in FIG. 1 to FIG. 6, identical reference numerals are intended to reference analogous, equivalent or identical structures.

FIG. 13 corresponds with FIG. 1, but while the field effect transistor of FIG. 1 is fabricated to include a pair of source/drain regions 24a and 24b (incorporating a pair of extension regions) as a starting point for further processing, the field effect transistor of FIG. 13 is fabricated only to include a pair of extension regions 23a and 23b as a starting point. Thus, a pair of source/drain regions 24a and 24b is absent within the third embodiment.

As is disclosed above within the context of the field effect transistor whose schematic cross-sectional diagram is illustrated in FIG. 1, the pair of extension regions 23a and 23b is formed using an ion implant method that uses the gate electrode 18 absent the pair of spacer layers 22a and 22b as a mask. Thus, within FIG. 13, the pair of spacer layers 22a and 22b is formed subsequent to forming the pair of extension regions 23a and 23b.

FIG. 14 shows the activation annealing treatment 26 that is used for thermally annealing the pair of extension regions 23a and 23b to form a pair of activated annealed extension regions 23a′ and 23b′. The activation annealing treatment 26 that is illustrated in FIG. 8 is otherwise analogous, equivalent or identical to the activation annealing treatment 26 that is illustrated in FIG. 2.

FIG. 15 shows a dose of amorphizing ions 28 that is used to amorphize the pair of activated annealed extension regions 23a′ and 23b′ to form a pair of amorphized extension regions 23a″ and 23b″. The dose of amorphizing ions 28 is otherwise generally analogous or equivalent to the dose of amorphizing ions 28 that is illustrated in FIG. 3, but may perhaps have a deeper penetration depth.

FIG. 16 shows a dose of antimony dopant ions 30. The dose of antimony dopant ions 30 is used for forming a pair of antimony doped amorphized source/drain regions 23a′″ and 23b′″ from the pair of amorphized extension regions 23a″ and 23b″. The dose of antimony dopant ions 30 is otherwise analogous equivalent of identical to the dose of antimony dopant ions 30 that is illustrated in FIG. 4, but within the third embodiment the dose of antimony dopant ions 30 is used to form a pair of source/drain regions. Thus, the pair of antimony doped amorphized source/drain regions 23a′″ and 23b′″ has a pair of conductor regions that comprise: (1) at a surface level both an antimony dopant and an arsenic or phosphorus co-dopant; and (2) a lower level only an antimony dopant.

Finally, FIG. 17 shows a laser surface annealing treatment 32. The laser surface annealing treatment 32 anneals the pair of antimony doped amorphized source/drain regions 23a′″ and 23b′″ to form therefrom a pair of recrystallized antimony doped source/drain regions 23a″″ and 23b″″. The laser surface annealing treatment 32 is otherwise analogous, equivalent or identical to the laser surface annealing treatment 32 that is illustrated in FIG. 5.

FIG. 18 is otherwise identical with FIG. 6, but with the presence of the pair of recrystallized antimony doped source/drain regions 23a″″ and 23b″″ rather than the pair of recrystallized antimony doped source/drain regions 24a″″ and 24b″″.

FIG. 18 shows a schematic cross-sectional diagram of a semiconductor structure in accordance with the third embodiment of the invention. The semiconductor structure comprises a field effect transistor comprising a pair of recrystallized antimony doped source/drain regions 23a″″ and 23b″″ that incorporate a pair of extension regions. The semiconductor structure uses a dose of antimony dopant ions 30, largely absent other dopant atoms, for forming contact region portions of the pair of recrystallized antimony doped source/drain regions 23a″″ and 23b″″.

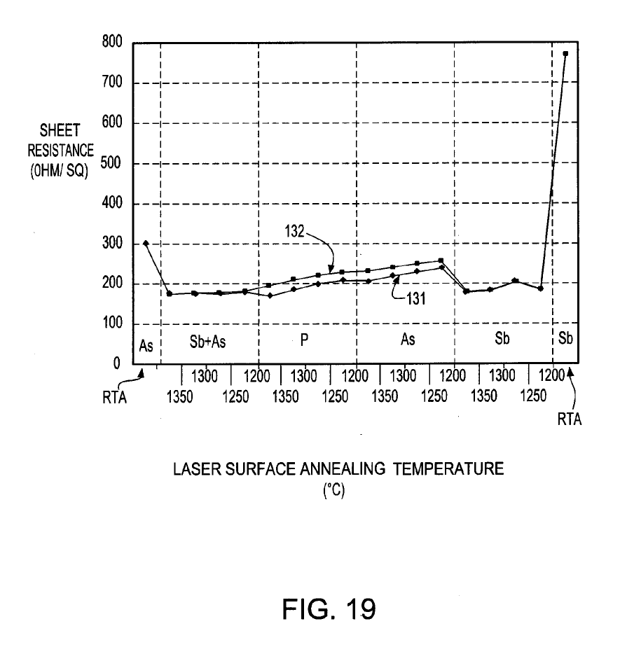

FIG. 19 shows a graph of Sheet Resistance versus Laser Surface Annealing Temperature for phosphorus, arsenic and antimony dopants individually within a silicon semiconductor substrate, as well as a mixture of antimony and arsenic dopants within the silicon semiconductor substrate. Also illustrated in FIG. 19 are two comparison data points for rapid thermal annealing activation of arsenic dopant atoms alone or antimony dopant atoms alone, within the silicon semiconductor substrate.

To obtain the experimental data that is illustrated in FIG. 19, either antimony (15 KeV), arsenic (8 KeV) or phosphorus (4 KeV) was ion implanted into an amorphized silicon semiconductor substrate at a dose of about 2e15 dopant atoms per square centimeter. The amorphized silicon semiconductor substrate was amorphized using a germanium amorphizing ion at a dose of about 5e14 germanium ions per square centimeter. The germanium amorphized silicon semiconductor substrate was amorphized to a depth deeper that an expected range for the antimony, arsenic or phosphorus dopants.

As a first pair of data points, an arsenic doped amorphized region and an antimony doped amorphized region were thermally annealed using a rapid thermal annealing method at a temperature of 1080° C. for a time period of 1-2 seconds. As is illustrated in FIG. 19, resultant sheet resistances were about 300 ohms per square for the recrystallized arsenic doped region and about 800 ohms per square for the recrystallized antimony doped region.

All remaining data points shown in FIG. 19 are derived from laser surface annealing treatments of the appropriate doped amorphized regions within a temperature range from 1200° C. to 1350° C. The remaining experimental data that is shown in FIG. 19 also includes: (1) sheet resistance measurements directly after laser surface annealing of the appropriate doped amorphized regions (as illustrated by the series of data points that corresponds with reference numeral 131); as well as (2) sheet resistance measurements with an additional 3 minutes thermal annealing at 500° C. after laser surface annealing of the appropriate doped amorphized regions (as illustrated by the series of data points that corresponds with reference numeral 132).

The data in FIG. 19 clearly show that additional thermal annealing of laser surface annealed recrystallized phosphorus doped regions or laser surface annealed recrystallized arsenic doped regions yields an arsenic doped semiconductor region or a phosphorus doped semiconductor region with reduced stability of sheet resistance with respect to additional thermal annealing. However, neither antimony doped regions, nor arsenic and antimony co-doped regions, nor by implication antimony and phosphorus co-doped regions, experience such a reduced stability of sheet resistance as a function of additional thermal annealing. Thus, the invention presumes that antimony (either alone or with another co-dopant) yields a thermally stable antimony doped region or antimony co-doped region within a semiconductor substrate. The invention is desirable for forming antimony co-doped regions within semiconductor substrates including, but not limited to: silicon, germanium, silicon-germanium alloy and related (i.e., carbide) semiconductor substrates. The semiconductor substrates may include, but are not limited to bulk semiconductor substrates and semiconductor-on-insulator substrates (where a silicon and/or germanium comprising semiconductor surface layer therein may be regarded as a “semiconductor substrate” within the context of the invention).

In accord with the experimental data above, the invention also contemplates that an antimony doped region (or an antimony co-doped region) once formed may not be subjected to an activation annealing treatment (such as but not limited to: a rapid thermal annealing treatment or a furnace annealing treatment) prior to a laser surface annealing treatment. Such a sequencing of annealing treatments will not provide the beneficial low and stable sheet resistance desired within the invention. Thus, within the preferred embodiments disclosed above, an activation annealing treatment 26 (i.e., FIG. 2, FIG. 8 and FIG. 14) must precede implantation of a semiconductor substrate with a dose of antimony ions 30 (i.e., FIG. 4, FIG. 10 and FIG. 16).

The preferred embodiments also contemplate that insofar as antimony ions may under certain circumstances have amorphizing properties, the dose of amorphizing ions 28 (FIG. 3, FIG. 9 and FIG. 15) may under certain circumstances be optional within the invention. The invention nonetheless still requires an amorphized antimony doped region be formed and subsequently laser surface annealed. Finally, the preferred embodiments also contemplate that a process sequencing of the dose of amorphizing ions 28 (i.e., FIG. 3, FIG. 9 and FIG. 15) and the dose of antimony ions 30 (i.e., FIG. 4, FIG. 10 and FIG. 16) may also under certain circumstances be interchangeable.

The preferred embodiments of the invention are illustrative of the invention rather than limiting of the invention. Revisions and modifications may be made to methods, materials, structures and dimensions in accordance with the preferred embodiments of the invention, while still providing an embodiment in accordance with the invention, further in accordance with the accompanying claims.

1. A method for fabricating a semiconductor structure comprising:
forming an antimony doped amorphized region within a semiconductor substrate; and
annealing the antimony doped amorphized region at a temperature from about 1050° C. to about 1400° C. for a time period from about 0.1 to about 10 milliseconds absent melting of the antimony doped amorphized region, to form an annealed antimony doped region.

2. The method of claim 1 wherein the forming step utilizes an antimony dopant ion and an amorphizing ion.

3. The method of claim 1 wherein the forming step utilizes an antimony dopant ion absent an amorphizing ion.

4. The method of claim 1 wherein the forming step further comprises at least one co-dopant.

5. The method of claim 4 wherein the at least one co-dopant comprises arsenic.

6. The method of claim 4 wherein the at least one co-dopant comprises phosphorus.

7. The method of claim 4 wherein the annealing is selected from the group consisting of a laser annealing and a flash annealing.

8. The method of claim 1 wherein the annealing at the temperature from about 1050° C. to about 1400° C. for the time period from about 0.1 to about 10 milliseconds is undertaken absent any prior activating thermal annealing of the antimony doped amorphized region.

9. A method for fabricating a semiconductor structure comprising:
forming an antimony doped amorphized region within a semiconductor substrate; and
laser annealing the antimony doped amorphized region to form a laser annealed antimony doped region, where the laser annealing provides a solid phase epitaxy of the antimony doped amorphized region absent melting of the antimony doped amorphized region.

10. The method of claim 9 wherein the forming step utilizes an antimony dopant ion and an amorphizing ion.

11. The method of claim 9 wherein the forming step utilizes an antimony dopant ion absent an amorphizing ion.

12. The method of claim 9 wherein the laser annealing step is undertaken at a temperature from about 1050° C. to about 1400° C.

13. The method of claim 12 wherein the laser annealing step is undertaken for a time period from about 0.1 to about 10 milliseconds.

14. The method of claim 9 wherein the laser annealing step is undertaken absent any prior activating thermal annealing of the antimony doped amorphized region.

15. A method for fabricating a semiconductor structure comprising:
forming an antimony co-doped amorphized region within a semiconductor substrate, the antimony co-doped amorphized region forther comprising at least one of a phosphorus co-dopant and an arsenic co-dopant; and
laser annealing the antimony co-doped amorphized region to form a laser annealed antimony co-doped region, wherein the laser annealing step provides a solid phase epitaxy of the antimony co-doped amorphized region absent melting of the antimony co-doped amorphized region.

16. The method of claim 15 wherein the forming step utilizes an antimony dopant ion, an amorphizing ion and at least one of a phosphorus dopant ion and an arsenic dopant ion.

17. The method of claim 15 wherein the forming step utilizes an antimony dopant ion and at least one of a phosphorus dopant ion and an arsenic dopant ion, absent an additional amorphizing ion.

18. The method of claim 15 wherein the laser annealing step is undertaken at a temperature from about 1050° C. to about 1400° C.

19. The method of claim 18 wherein the laser annealing step is undertaken for a time period from about 0.1 to about 10 milliseconds.

20. The method of claim 15 wherein the laser annealing step is undertaken absent any prior thermal annealing of the antimony co-doped amorphized region.
